(19) United States
(12) Patent Application Publication
(10) Pub. No.: US 2009/0147891 A1
(43) Pub. Date: Jun. 11, 2009

(54) AUDIO SIGNAL DEMODULATION APPARATUS

(76) Inventor: Hiroki Furukawa, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/088,020

(22) PCT Filed: Oct. 23, 2006
(86) PCT No.: PCT/JP2006/321050

§ 371 Date: Mar. 25, 2008

(30) Foreign Application Priority Data
Oct. 25, 2005 (JP) 2005-310380
Dec. 9, 2005 (JP) 2005-357027

(51) Int. Cl. H03D 1/04

(52) U.S. Cl. 375/346

(57) ABSTRACT

An FM demodulation apparatus (200) includes: an analog-to-digital conversion unit (201) which converts a modulated analog signal into a digital signal; a quadrature conversion unit (202) which converts, into two mutually quadratic baseband signals, the digital signal converted by the analog-to-digital conversion unit (202); a band limiting unit (205) which limits a frequency component exceeding a possible maximum frequency of the modulated wave, in the two baseband signals converted by the quadrature conversion unit (202); a detecting unit (206) which obtains a demodulated signal from the two baseband signals that have been band-limited by the band limiting unit (205); and a pulse noise suppressing unit (204) which suppresses pulse noise included in the signals inputted to the band limiting unit (205).

### TECHNICAL FIELD

The present invention relates to FM demodulation apparatuses which perform FM demodulation by digital signal processing of an FM modulated wave, and particularly to a technique for suppressing sound quality deterioration due to influence of pulse noise.

### BACKGROUND ART

Conventionally, FM demodulation apparatuses which perform FM demodulation by digital signal processing of an FM modulated wave have been proposed (see Patent Reference 1, for example). Furthermore, pulse noise cancellation apparatuses for FM receivers have also been proposed (see Patent Reference 2, for example).

FIG. 1 is a diagram showing the structure of an FM demodulation apparatus 100 disclosed in Patent Reference 1. The FM demodulation apparatus 100 includes an analog-to-digital conversion unit 100, a quadrature conversion unit 102, a band limiting unit 103, and a wave detecting unit 104.

The analog-to-digital conversion unit 101 converts an FM modulated analog intermediate-frequency signal into a digital signal. The FM modulated signal inputted to the analog-to-digital conversion unit 101 is a commonly used intermediate-frequency signal of 10.7 MHz. Furthermore, the sampling frequency of the analog-to-digital conversion unit 101 is 40 MHz which is at least double the input signal frequency.

The quadrature conversion unit 102 converts the digital signal outputted from the analog-to-digital conversion unit 101 into two baseband signals. Specifically, the quadrature conversion unit 102 obtains two mutually quadratic baseband signals by multiplying the digital signal outputted from the analog-to-digital conversion unit 101 with a cosine wave and sine wave which are of 10.7 MHz. The baseband signal obtained from the multiplication with a cosine wave is called an I-signal, and the baseband signal obtained from the multiplication with the sine wave is called a Q-wave.

The band limiting unit 103 limits, from each of the two baseband signals outputted from the quadrature conversion unit 102, signals of bands that are not necessary in FM demodulation. A low-pass filter is used as the band limiting unit 103. In other words, from the two baseband signals outputted from the quadrature conversion unit 102, the band limiting unit 103 allows a signal of a band (for example, ±100 kHz) that is necessary for FM demodulation to pass. The two baseband signals that have been band-limited are normally downsampled in order to reduce processing and memory amount. Here, the sampling frequency is downsampled from 40 MHz to 312.5 kHz.

FIG. 2 is a diagram showing the configuration of the wave detecting unit 104. The wave detecting unit 104 includes a phase detecting unit 104a which detects the respective phases of the two signals outputted from the band limiting unit 103, and a differentiating unit 104b which obtains an FM demodulated signal by calculating the difference value (differentiation) of the detected phases. Specifically, the arctangent of the downsampled I-signal and Q-signal are calculated, and a phase θ=arctan (Q/I) is detected for each 312.5 kHz sample. Here, when the sample number is j, the difference value between the phase of a one-later sample, Δθ(j)=θ(j)−θ(J−1), denotes the instantaneous frequency, and thus such difference value Δθ becomes the FM demodulated signal.

FIG. 3 is a diagram showing the configuration of the pulse noise cancellation apparatus 110 disclosed in Patent Reference 2. The pulse noise cancellation apparatus 110 is an apparatus which suppresses pulse noise that has mixed-in with the FM demodulated signal (composite signal), and includes a noise detecting unit 111, a data interpolation unit 112, and a memory 113.

The noise detecting unit 111 extracts the high-frequency component of the FM demodulated signal using a high-pass filter, and detects pulse noise depending on the signal level of the high-pass filter output. The FM demodulated signal is sequentially inputted to the First In, First Out formatted memory 113, and the newest sample is stored. When pulse noise is detected by the noise detecting unit 111, the data interpolation unit 112 removes the pulse noise portion from the sample stored in the memory 113, and cancels pulse noise by interpolating data into the removed portion. The data interpolated into the removed portion is estimated using the samples (stored in the memory 113) surrounding the removed portion.

### Patent Reference 1: Japanese Unexamined Patent Application Publication No. 2000-68749

### Patent Reference 2: Japanese Unexamined Patent Application Publication No. 5-315983

### DISCLOSURE OF INVENTION

### Problems that Invention is to Solve

As described above, by providing the conventional pulse noise cancellation apparatus 110 in a subsequent stage of the conventional FM demodulation apparatus 100, it is possible to suppress the pulse noise that has mixed-in with the FM demodulated signal. However, in the case where the FM demodulation apparatus 100 is provided in a vehicle for example, there are instances where pulse noise that is significantly larger than the FM demodulated signal is generated from the engine, and so on, and mixes-in through the antenna. Pulse noise is also generated when operating electric side mirrors and when flashing headlights between high and low beam. In such cases, it becomes difficult to effectively remove pulse noise with the conventional pulse noise cancellation apparatus 110.

Hereinafter, the reason for the difficulty in effectively removing pulse noise shall be described.

FIG. 4 is a diagram showing the impulse response of a low-pass filter used as the band limiting unit 103. In order to detect phases with a wave detecting unit 105, it is preferable that the low-pass filter is linear phased and, generally, a symmetrical Finite Impulse Response (FIR) filter is used. As shown in the figure, when an impulse is inputted to the low-pass filter, the width of the response thereof expands in the temporal axis direction. Such an expansion of the response width in the temporal axis direction is due to a physical property of the low-pass filter.

FIG. 5 is a diagram showing the waveform of signals outputted from the respective constituent units of the conventional FM demodulation apparatus 100. The horizontal axis represents time, and the vertical axis represents amplitude. In order to facilitate the viewing of the figure, the respective waveforms are laid-out so that noise appears in the center position of the horizontal axis.

(a) in FIG. 5 shows a waveform W11 of a signal outputted from the analog-to-digital conversion unit 101. Here, the appearance is shown for the case where sampling at 40 MHz is assumed, and pulse noise, which is significantly larger than the FM demodulated signal, mixes-in at a certain timing T.

(b) in FIG. 5 shows a waveform W12 of the I-signal and a waveform W13 of the Q-signal outputted from the band limiting unit 103. Here, the case of downsampling to 312.5 kHz is assumed. As shown in the figure, mixed-in pulse noise expands in the temporal axis direction when outputted from the band limiting unit 103. Such an expansion of pulse noise in the temporal axis direction is due to a physical property of the low-pass filter. Note that ΔT in the figure means that the position of the noise is laid-out in the center position of the horizontal axis.

(c) in FIG. 5 shows a waveform W14 of a signal (phase θ) outputted from the phase detecting unit 104a included in the wave detecting unit 104. As shown in the figure, the phase is distorted due to the influence of the pulse noise which has expanded in the temporal axis direction.

(d) in FIG. 5 shows a waveform W15 of the signal (difference value Δθ), in other words the FM demodulated signal, outputted from the differentiating unit 104b included in the wave detecting unit 104. As shown in the figure, the influence of the noise caused by mixed-in pulse noise expands in the temporal axis direction.

In this manner, according to the conventional FM demodulation apparatus 100, when pulse noise which is significantly larger than the FM demodulated signal mixes-in, this pulse noise expands in the temporal axis direction and appears in the FM demodulated signal. Even when the removal of pulse noise that has expanded in the temporal axis direction in this manner is attempted using the conventional pulse noise cancellation unit 110, accurate estimation of the pulse noise term is not possible since the rise and fall of noise is unclear, as shown in (d) in FIG. 5. Therefore, proper interpolation of data is difficult and pulse noise cannot be sufficiently removed, causing significant deterioration of sound quality.

The present invention is conceived in view of the aforementioned problem and has as an objective to provide an audio signal demodulation apparatus which can sufficiently suppress pulse noise even in the case where large pulse noise mixes-in.

### Means to Solve the Problems

In order to achieve the aforementioned object, the audio signal demodulation apparatus according to the present invention is an audio signal demodulation apparatus which demodulates a modulated wave obtained by modulating an audio signal, the audio signal demodulation apparatus including: an analog-to-digital conversion unit which converts a modulated analog signal into a digital signal; a quadrature conversion unit which converts, into two mutually quadratic baseband signals, the digital signal converted by the analog-to-digital conversion unit; a band limiting unit which limits a frequency component in the two baseband signals converted by the quadrature conversion unit, the frequency component exceeding a possible maximum frequency of the modulated wave; a detecting unit which obtains a demodulated signal from the two baseband signals that have been band-limited by the band limiting unit; and a pulse noise suppressing unit which suppresses pulse noise included in the signals inputted to the band limiting unit. With this, pulse noise is suppressed before band limiting, and thus pulse noise can be suppressed precisely.

Here, the pulse noise suppressing unit may be provided between the quadrature conversion unit and the band limiting unit. As long as the pulse noise suppressing unit is located at least at a preceding stage to the band limiting unit, it is possible, compared to that which is conventional, to suppress pulse noise from expanding in a temporal axis direction.

Furthermore, the audio signal demodulation apparatus may further include: a preprocessing band limiting unit which limits a frequency component exceeding the maximum frequency, as preprocessing for the suppression of the pulse noise, wherein the pulse noise suppressing unit may be provided between the preprocessing band limiting unit and the band limiting unit. With this, frequencies other than what is desired can be limited by the band limiting unit, and thus it is possible to prevent misdetection of pulse noise by the pulse noise detecting unit.

Furthermore, the pulse noise suppressing unit may be provided between the analog-to-digital conversion unit and the quadrature conversion unit. As long as the pulse noise suppressing unit is located at least at a preceding stage to the band limiting unit, it is possible, compared to that which is conventional, to suppress pulse noise from expanding in a temporal axis direction.

Furthermore, the pulse noise suppressing unit may detect, as a pulse noise term, a term in which amplitude values of the inputted signals exceed a threshold. With this, the presence of pulse noise is detected depending on the threshold, and thus pulse noise/not pulse noise determination criteria can be changed easily. For example, the pulse noise suppressing unit may set, as the amplitude values, a sum of squares or a square root of a sum of squares of the inputted signals. Alternatively, the pulse noise suppressing unit may set, as the amplitude values, a sum or an average of absolute values of the inputted signals. In addition, the pulse noise suppressing unit may set, as the threshold, a predetermined multiple of an average of absolute values of the inputted signals.

Furthermore, the pulse noise suppressing unit may output an average of amplitude values of the inputted signals for a term in which the pulse noise is detected, and output the inputted signals for a term in which the pulse noise is not detected. With this, an average of the respective amplitude values of the two baseband signals outputted from the quadrature conversion unit is outputted for the term in which the pulse noise is detected, and thus pulse noise can be sufficiently suppressed.

Furthermore, the present invention can be implemented, not only as the aforementioned audio signal demodulation apparatus, but also as a car radio which includes the characteristic units included in the aforementioned audio signal demodulation apparatus, an audio signal demodulation method having as steps the characteristic units of the aforementioned audio signal demodulation unit, and a program which causes a computer to execute such steps. In addition, it goes without saying that such a program can be distributed via a recording medium such as a CD-ROM, and a transmission medium such as the Internet.

### EFFECTS OF THE INVENTION

As is clear from the above description, with the audio signal demodulation apparatus according to the present invention, pulse noise is suppressed before band-limiting, and thus the pulse noise can be suppressed precisely. In other words, the problem of pulse noise expanding in the temporal axis direction can be avoided, and it is possible to suppress the generation of significant noise in the FM demodulated signal.

Furthermore, since it is possible to perform band limiting in plural stages, there is the advantage of lessening instances where signals other than pulse noise, such as an FM signal of another frequency, are mistakenly detected as pulse noise. In addition, since sampling frequencies can be reduced before detecting and suppressing pulse noise, there is the advantage that the amount of computing for detecting and suppressing the pulse noise is lessened. Moreover, since pulse noise can be detected and suppressed before quadrature conversion, there is the advantage that the configuration for detecting and suppressing the pulse noise is simplified.

In particular, in the case where the present invention is applied as a car radio, it is possible to suppress pulse noise generated when operating electric side mirrors or when flashing headlights between high and low beam, and thus the practical value of the present invention is extremely high.

### BRIEF DESCRIPTION OF DRAWINGS

FIG. 1 is a diagram showing the configuration of a conventional FM demodulation apparatus.

FIG. 2 is a diagram showing the configuration of a wave detecting unit.

FIG. 3 is a diagram showing the configuration of a conventional pulse noise cancellation apparatus.

FIG. 4 is a diagram showing an impulse response of a low-pass filter.

FIG. 5, (a), (b), (c), (d), is a diagram showing output waveforms of a conventional FM demodulation apparatus.

FIG. 6 is a diagram showing a scene in which the present invention is applied.

FIG. 7 is a diagram showing the configuration of the FM demodulation apparatus in the first embodiment.

FIG. 8 is a diagram showing the configuration of the wave detecting unit in the first embodiment.

FIG. 9 is a diagram showing the configuration of the pulse noise detecting unit in the first embodiment.

FIG. 10 is a diagram showing the configuration of the pulse noise suppressing unit in the first embodiment.

FIG. 11 is a diagram showing the computing equation for the short-term average level.

FIG. 12 is a flowchart showing the operation of the FM demodulation apparatus in the first embodiment.

FIG. 13, (a), (b), (c), (d), (e), (f), is a diagram showing output waveforms of the FM demodulation apparatus in the first embodiment.

FIG. 14 is a diagram showing the configuration of the FM demodulation apparatus in the second embodiment.

FIG. 15 is a diagram showing the configuration of the first band limiting unit in the second embodiment.

FIG. 16 is a diagram showing the impulse response of the first band limiting unit in the second embodiment.

FIG. 17 is a diagram showing the configuration of the second band limiting unit in the second embodiment.

FIG. 18 is a diagram showing the impulse response of the second band limiting unit in the second embodiment.

FIG. 19 is a flowchart showing the operation of the FM demodulation apparatus in the second embodiment.

FIG. 20 is a diagram showing the configuration of the FM demodulation apparatus in the third embodiment.

FIG. 21 is a diagram showing the configuration of the pulse noise detecting unit in the third embodiment.

FIG. 22 is a diagram showing the configuration of the pulse noise suppressing unit in the third embodiment.

FIG. 23 is a flowchart showing the operation of the FM demodulation apparatus in the third embodiment.

FIG. 24 is a diagram showing a different configuration of the pulse noise detecting unit in the first embodiment.

FIG. 25 is a diagram showing a different configuration of the pulse noise detecting unit in the third embodiment.

FIG. 26 is a diagram showing an example of the case where the constituent units of the FM demodulation apparatus are made as an integrated circuit.

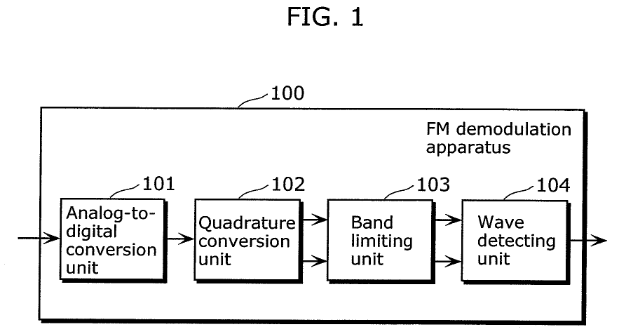

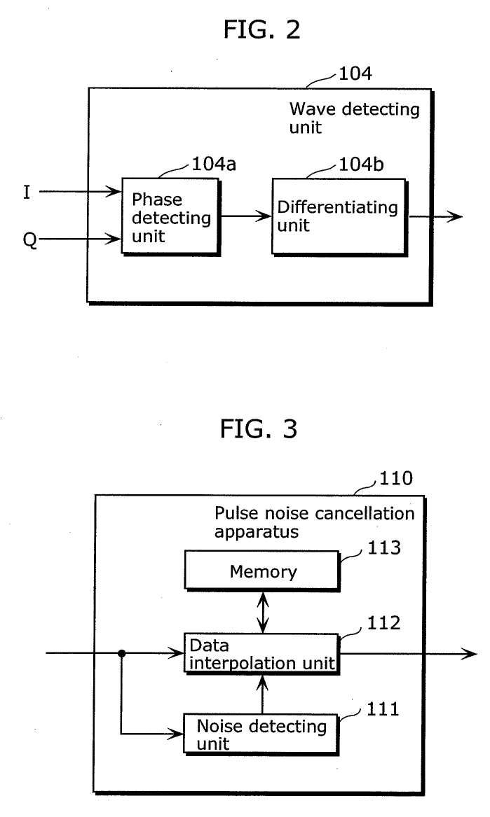

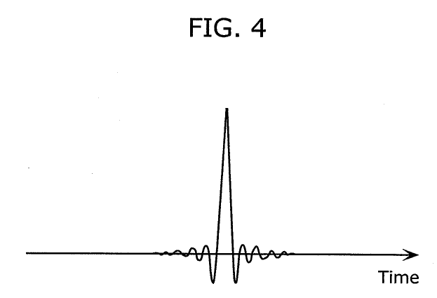

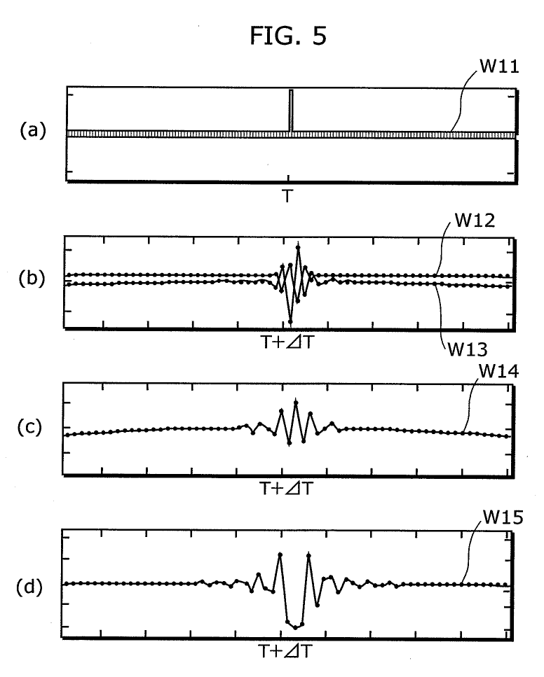

### NUMERICAL REFERENCES

200 FM demodulation apparatus
201 Analog-to-digital conversion unit
202 Quadrature conversion unit
203 Pulse noise detecting unit
204 Pulse noise suppressing unit
205 Band limiting unit
206 Wave detecting unit
2031 Amplitude detecting unit
2033 High-pass filtering unit
2034 Amplitude detecting unit
2035 Threshold setting unit
2036 Determining unit
2041 First average level computing unit
2042 Second average level computing unit
2043 Selecting unit
210 Pulse noise detecting unit
2101 Amplitude detecting unit
2102 Average level detecting unit
2103 Threshold setting unit
2104 Determining unit
300 FM demodulation apparatus
301 First band limiting unit
302 Pulse noise detecting unit
303 Pulse noise suppressing unit
304 Second band limiting unit
3011 First low-pass filtering unit
3012 First downsampling unit
3041 Second low-pass filtering unit
3042 Second downsampling unit
400 FM demodulation apparatus
401 Pulse noise detecting unit
402 Pulse noise suppressing unit
4021 Average level computing unit
4022 Selecting unit

### BEST MODE FOR CARRYING OUT THE INVENTION

Hereinafter, each embodiment of the FM demodulation apparatus according to the present invention shall be described with reference to the drawings.

### First Embodiment

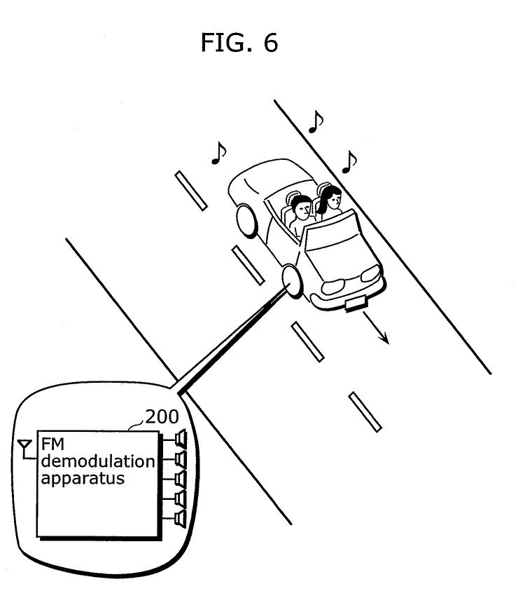

FIG. 6 is a diagram showing a scene in which the present embodiment is applied. Here, it is shown that an FM demodulation apparatus 200 in the first embodiment is provided in a car as a car FM radio. As already described, in the case where the FM demodulation apparatus 200 is provided in a vehicle, there is the problem that pulse noise that is significantly larger than the FM demodulated signal is generated from the engine, and so on, and mixes-in through the antenna. Pulse noise is also generated when operating electric side mirrors and when flashing headlights between high and low beam.

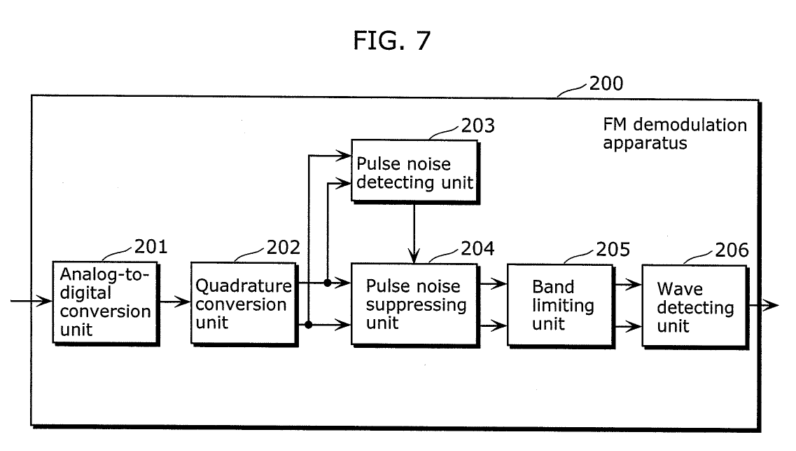

FIG. 7 is a diagram showing the configuration of the FM demodulation apparatus 200 in the first embodiment. The FM demodulation apparatus 200 functionally includes an analog-to-digital conversion unit 201, a quadrature conversion unit 202, a pulse noise detecting unit 203, a pulse noise suppressing unit 204, a band limiting unit 205, and a wave detecting unit 206. In the following description, there are cases where the pulse noise detecting unit 203 and the pulse noise suppressing unit 204 are collectively referred to as a “pulse noise suppression unit”.

The functions of the analog-to-digital conversion unit 201, the quadrature conversion unit 202, the band limiting unit 205, and the wave detecting unit 206 are the same as those in the conventional example. In other words, the analog-to-digital conversion unit 201 is a conversion circuit, and the like, which converts an FM modulated analog signal into a digital signal. The quadrature conversion unit 202 is a conversion circuit, and the like, which converts the digital signal outputted from the analog-to-digital conversion unit 201 into two mutually quadratic baseband signals (an I-signal and a Q-signal). The band limiting unit 205 is a low band limiting filter, and the like, which limits low-band signals that are not necessary in FM demodulation, from the two baseband signals outputted from the pulse noise suppressing unit 204. The band limiting unit 205 may also include a downsampling unit which reduces sampling frequencies.

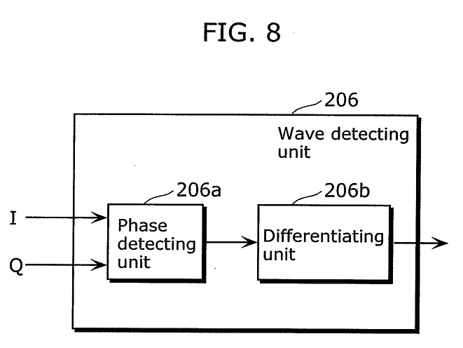

FIG. 8 is a diagram showing the configuration of the wave detecting unit 206. The wave detecting unit 206 is a wave detecting circuit, and the like, which obtains an FM demodulated signal from the two baseband signals that have been band-limited by the band limiting unit 205. The wave detecting unit 206 functionally includes a phase detecting unit 206a and a differentiating unit 206b. The phase detecting unit 206a detects the phases of the two baseband signals outputted from the pulse noise suppressing unit 204. The differentiating unit 206b obtains an FM modulated signal by calculating a difference value (differentiation) of the phases detected by the phase detecting unit 206b.

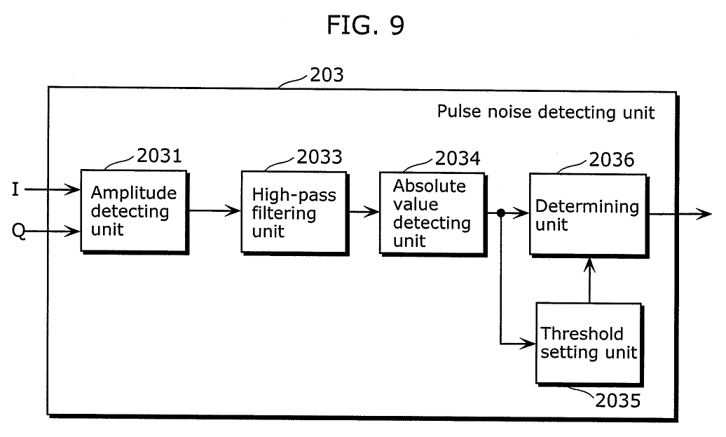

FIG. 9 is a diagram showing the configuration of the pulse noise detecting unit 203. The pulse noise detecting unit 203 is a detecting circuit, and the like, which detects pulse noise included in the two baseband signals outputted from the quadrature conversion unit 202, and functionally includes an amplitude detecting unit 2031, a high-pass filtering unit 2033, an absolute value detecting unit 2034, a threshold setting unit 2035, and a determining unit 2036. The amplitude detecting unit 2031 calculates the amplitude values of the two baseband signals outputted from the quadrature conversion unit 202, specifically, the sum of squares or the square root of the sum of the squares of the two baseband signals outputted from the quadrature conversion unit 202. The high-pass filtering unit 2033 detects the high-frequency component of an inputted signal. The absolute value detecting unit 2034 calculates the absolute value of the output of the high-pass filtering unit 2033. The threshold setting unit 2035 sets a threshold based on the output of the absolute value detecting unit 2034. The determining unit 2036 compares the output of the absolute value detecting unit 2034 and the output (threshold) of the threshold setting unit 2035, and performs pulse noise determination.

The amplitude values of the two baseband signals consisting of the I-signal and the Q-signal, that is, the output of the amplitude detecting unit 2031 are known to be values that are proportionate to the electric field intensity. In other words, when pulse noise mixes-in during FM modulated wave reception, the value of the signal outputted from the amplitude detecting unit 2031 changes abruptly in response to the pulse noise. This abrupt change is detected by the high-pass filtering unit 2033, and the absolute value thereof is detected by the absolute value detecting unit 2034. The threshold value setting unit 2035 detects the average of the signals, outputted from the absolute value detecting unit 2034, and sets a predetermined multiple thereof, for example a 3-fold value, as the threshold. The determining unit 2035 determines, as the pulse noise term, the term in which the amplitude values of the signal outputted from the absolute value detecting unit 2034 exceed the threshold.

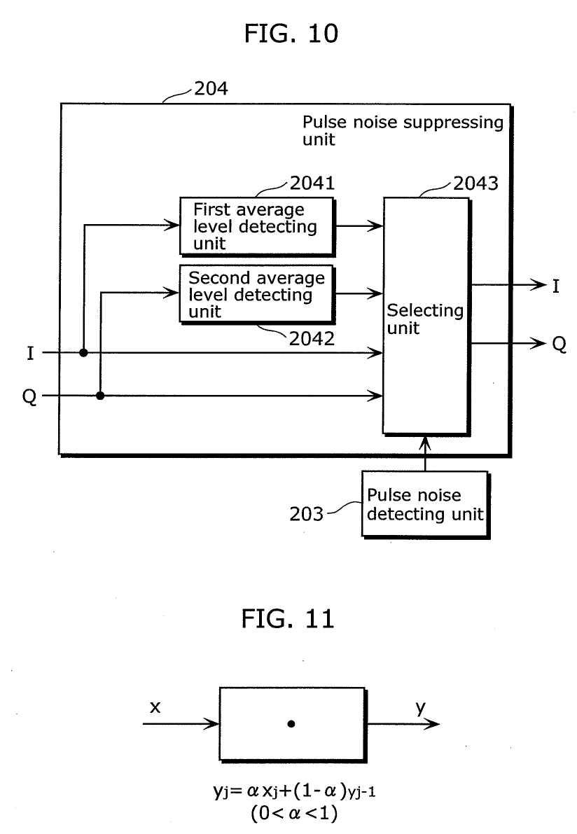

FIG. 10 is a diagram showing the configuration of the pulse noise suppressing unit 204. The pulse noise suppressing unit 204 is a suppressing circuit, and the like, which suppresses the pulse noise detected by the pulse noise detecting unit 203, for the two baseband signals outputted from the quadrature conversion unit 202. The pulse noise suppressing unit 204 functionally includes a first average level computing unit 2041, a second level computing unit 2041, and a selecting unit 2043.

The first average level computing unit 2041 computes a short-term average level of the I-signal outputted from the quadrature conversion unit 202. The second average level computing unit 2042 computes the short-term average level of the Q-signal outputted from the quadrature conversion unit 202. FIG. 11 is a diagram showing the computing equation for the short-term average level. As shown in the figure, the short-term average level, when input value is x and the output value is y, can be calculated by a general computing equation.

The selecting unit 2043 selects and outputs the short-term average level of the I-signal outputted from the first average level computing unit 2041 and likewise selects and outputs the short-term average level of the Q-signal outputted from the second average level computing unit 2042, for the pulse noise term detected by the pulse noise detecting unit 203. On the other hand, for the term other than the pulse noise term, the selecting unit 2043 selects and outputs the I-signal and the Q-signal outputted from the quadrature conversion unit 202.

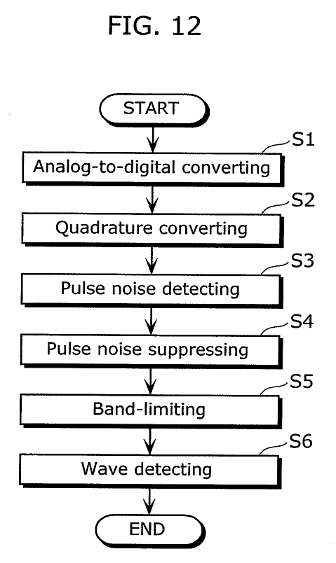

FIG. 12 is a flowchart showing the operation of the FM demodulation apparatus 200 in the first embodiment. First, the analog-to-digital conversion unit 201 converts an FM modulated analog signal into a digital signal (S1). Next, the quadrature conversion unit 202 quadrature-converts the digital signal outputted from the analog-to-digital conversion unit 201 into two mutually quadratic baseband signals (S2). Next, the pulse noise detecting unit 203 detects the pulse noise included in the two baseband signals outputted from the quadrature conversion unit 202 (S3). Next, the pulse noise suppressing unit 204 suppresses the pulse noise detected by the pulse noise detecting unit 203, in the two baseband signals outputted from the quadrature conversion unit 202 (S4). Next, the band limiting unit 205 limits bands that are not necessary in FM demodulation (the frequency component exceeding the possible maximum frequency of an FM modulated wave), from the two baseband signals outputted from the pulse noise suppressing unit 204 (S5). Lastly, the wave detecting unit 206 obtains an FM demodulated signal from the two baseband signals that have band-limited by the band limiting unit 205. Note that since the details of the respective operations are as described previously, detailed description is omitted here.

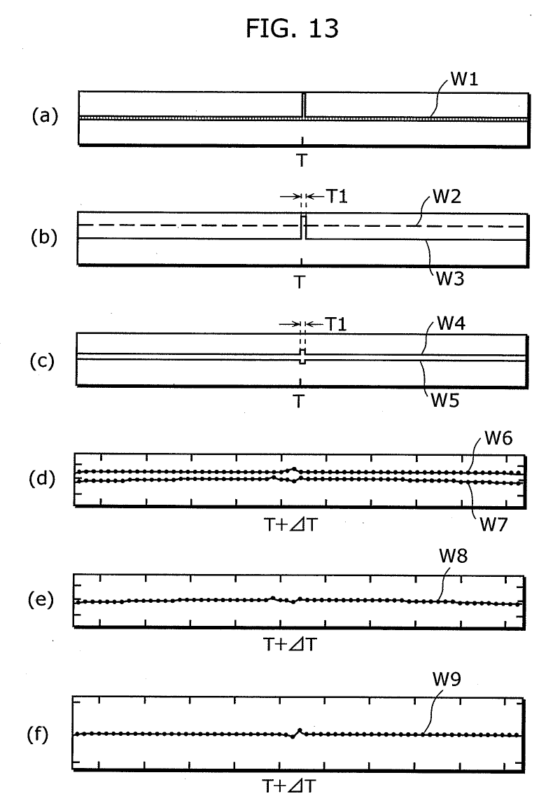

FIG. 13 is a diagram showing the waveforms of the signals outputted from the respective constituent components of the FM demodulation apparatus 200 in the first embodiment. The horizontal axis represents time, and the vertical axis represents amplitude. In order to facilitate the viewing of the figure, the respective waveforms are laid-out so that noise appears in the center position of the horizontal axis. Note that ΔT in the figure means that the position of the noise is laid-out in the center position of the horizontal axis.

(a) in FIG. 13 shows a waveform W1 of a signal outputted from the analog-to-digital conversion unit 201. Here, the appearance is shown in the case where sampling at 40 MHz is assumed, and pulse noise, which is significantly larger than the FM demodulated signal, mixes-in at a certain timing T.

(b) in FIG. 13 shows, with a broken line, a waveform W2 of the signal outputted from the threshold setting unit 2035, and shows, with a solid line, a waveform W3 of the signal outputted from the amplitude detecting unit 2031. A term T1 in which the solid line surpasses the broken line is determined to be the pulse noise term.

(c) in FIG. 13 shows a waveform W4 of the I-signal and a waveform W5 of the Q-signal outputted from the pulse noise suppressing unit 204. For the pulse noise term T1, the short-term average level of the I-signal outputted from the first average level computing unit 2041 is outputted, and the short-term average level of the Q-signal outputted from the second average level computing unit 2042 is also outputted. On the other hand, for the term other than the pulse noise term, the I-signal and the Q-signal outputted from the quadrature conversion unit 202 is outputted. In this manner, for the pulse noise term T1, the short-term average level of the I-signal and the Q-signal are outputted, and the pulse noise is suppressed.

(d) in FIG. 13 shows a waveform W6 of the I-signal and a waveform W7 of the Q-signal outputted from the band limiting unit 205. Here, the case of downsampling to 312.5 kHz is assumed. As shown in the figure, since the mixed-in pulse noise is suppressed by the pulse noise suppressing unit 204, the pulse noise only expands slightly in the temporal axis direction.

(e) in FIG. 13 shows a waveform W8 of the signal outputted from the phase detecting unit 206a included in the wave detecting unit 206. As shown in the figure, since the pulse noise only expands slightly in the temporal axis direction, significant phase distortion does not occur.

(f) in FIG. 13 shows a waveform W9 of the signal outputted from the differentiating unit 104b included in the wave detecting unit 104, in other words the FM demodulated signal. As shown in the figure, the generation of noise due to pulse noise is suppressed even with regard to the FM demodulated signal.

As described thus far, since the FM demodulation apparatus 200 in the first embodiment adopts a configuration which includes the pulse noise detecting unit 203 and the pulse noise suppressing unit 204 between the quadrature conversion unit 202 and the band limiting unit 205, the FM demodulation apparatus 200 can precisely suppress pulse noise before band-limiting. In other words, as a result of being able to avoid the problem of pulse noise expanding in the temporal axis direction and being able to suppress the generation of significant noise in the FM demodulated signal, it becomes possible to reduce sound quality deterioration due to pulse noise.

Note that although a configuration which includes the quadrature conversion unit 202 in a subsequent stage to the analog-to-digital conversion unit 201 is exemplified here, quadrature conversion may be performed during analog signal processing. In other words, the quadrature conversion unit outputs two mutually quadratic analog signals, by performing quadrature conversion during analog signal processing. These two analog signals are converted into digital signals by the analog-to-digital conversion unit. Even in this case, the same effect as that described above can be obtained by suppressing pulse noise before band limiting.

Furthermore, although the amplitude detecting unit 203 calculates the sum of squares or the square root of the sum of the squares of the I-signal and the Q-signal here, the present invention is not limited to such. For example, even when the amplitude detecting unit 2031 is made to detect the sum or the average of the respective absolute values of the I-signal and the Q-signal, the same effect as that described above can be obtained.

### Second Embodiment

Although a configuration which includes only one band limiting unit is exemplified in the above-described first embodiment, band limiting can be performed by being separated into plural stages. In the second embodiment, a configuration which includes two band limiting units shall be described.

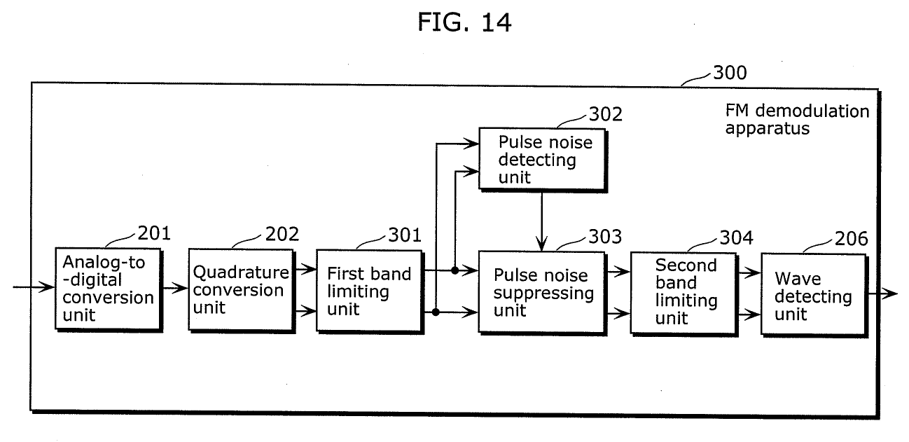

FIG. 14 is a diagram showing the configuration of an FM demodulation apparatus 300 in the second embodiment. As in the first embodiment, the FM demodulation apparatus 300 is a car FM radio, and the like, which performs FM demodulation of an FM modulated wave by digital signal processing, and which functionally includes the analog-to-digital conversion unit 201, the quadrature conversion unit 202, a first band limiting unit 301, a pulse noise detecting unit 302, a pulse noise suppressing unit 303, a second band limiting unit 304, and the wave detecting unit 206. The functions of the analog-to-digital conversion unit 201, the quadrature conversion unit 202, and the wave detecting unit 206 are the same as those in the first embodiment.

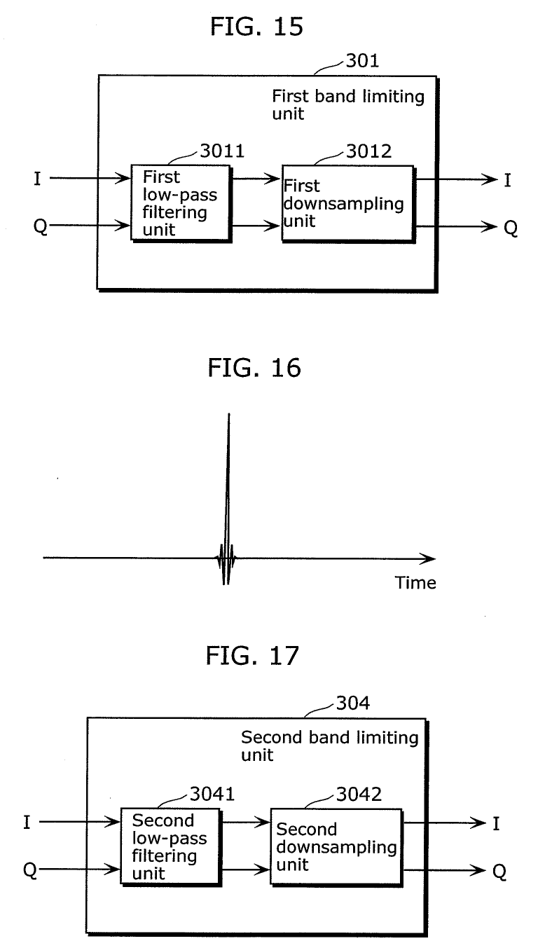

FIG. 15 is a diagram showing the configuration of the first band limiting unit 301. The first band limiting unit 301 includes a first low-pass filtering unit 3011 and a first downsampling unit 3012. The first low-pass filtering unit 3011 performs band-limiting on the two baseband signals outputted from the quadrature conversion unit 202. The first downsampling unit 3012 reduces sampling frequencies. In the present embodiment, the sampling frequency of the analog-to-digital conversion unit 201 is 40 MHz, the cut-off frequency of the first low-pass filtering unit 3011 is 460 kHz, and the 40 MHz sampling frequency of the analog-to-digital conversion unit 201 is downsampled, to 1/64, to 625 kHz.

FIG. 16 is a diagram showing the impulse response of the low-pass filter used as the first low-pass filtering 3011. In this low-pass filter, a symmetrical FIR filter is used. Although it would seem that by doing so the pulse noise will expand in the temporal axis direction as in the conventional example, since the cut-off frequency of the FIR filter is broad at 460 kHz, the impulse response does not expand significantly in the temporal axis direction, as shown in the figure. In other words, since the pulse noise does not expand significantly in the temporal axis direction even after passing through the first low-pass filtering unit 3011, the pulse noise can be sufficiently suppressed by the pulse noise suppressing unit 302 in the subsequent stage.

FIG. 17 is a diagram showing the configuration of the second band limiting unit 304. The second band limiting unit 304 includes a second low-pass filtering unit 3041 and a second downsampling unit 3042. The second low-pass filtering unit 3041 performs band-limiting on the two baseband signals outputted from the pulse noise suppressing unit 303. The second downsampling unit 3042 reduces sampling frequencies. In the present embodiment, the cut-off frequency of the second low-pass filtering unit 3041 is 120 kHz, and the 625 kHz sampling frequency of the first downsampling unit 3012 is downsampled, to ½, to 312.5 kHz, by the second downsampling unit 3042.

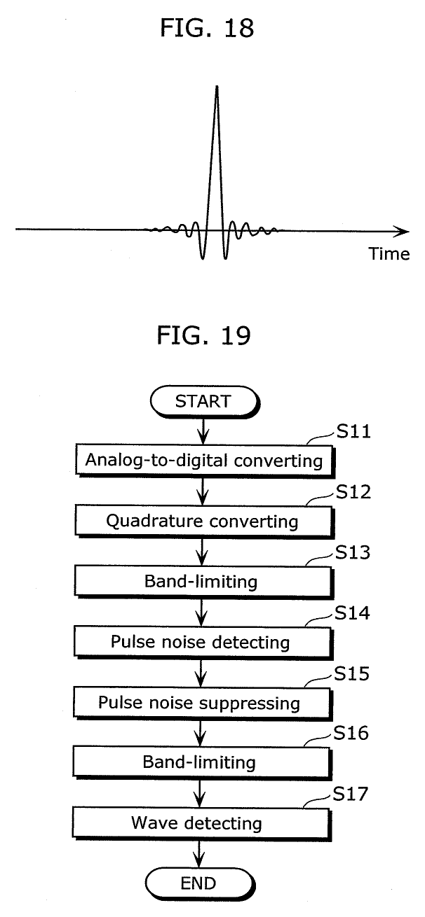

FIG. 18 is a diagram showing the impulse response of the low-pass filter used as the second low-pass filtering unit 3041. In this low-pass filter, a symmetrical FIR filter is also used. Since the cut-off frequency is narrow at 120 kHz, the impulse response expands significantly in the temporal axis direction, as shown in the figure. Therefore, it is necessary to sufficiently suppress the pulse noise in the pulse noise suppressing unit 302 before it passes through the second low-pass filtering unit 3041.

The pulse noise detecting unit 302 detects pulse noise, with the two baseband signals outputted from the first band limiting unit 301 as input signals. The point of difference with the pulse noise detecting unit 203 in the first embodiment is only the difference in the sampling frequency of the inputted signals.

The pulse noise suppressing unit 303 suppresses pulse noise, with the two baseband signals outputted from the first band limiting unit 301 as input signals. Although, in contrast to the pulse noise suppressing unit 204 in the first embodiment which has the signals outputted from the quadrature conversion unit 202 as input signals, the pulse noise suppressing unit 303 in the second embodiment has the signals outputted from the first band limiting unit 301 as input signals, all other points are the same.

FIG. 19 is a flowchart showing the operation of the FM demodulation apparatus 300 in the second embodiment. First, the analog-to-digital conversion unit 201 converts an FM modulated analog signal into a digital signal (S11). Next, the quadrature conversion unit 202 quadrature-converts the digital signal outputted from the analog-to-digital conversion unit 201 into two mutually quadratic baseband signals (S12). Next, the first band limiting unit 301 limits a first band that is not necessary in FM demodulation (the frequency component exceeding the possible maximum frequency of an FM modulated wave), from the two baseband signals outputted from the pulse noise suppressing unit 204 (S13). Next, the pulse noise detecting unit 302 detects pulse noise included in the two baseband signals that have been band-limited by the first band limiting unit 301 (S14). Next, the pulse noise suppressing unit 303 suppresses the pulse noise detected by the pulse noise detecting unit 302, in the two baseband signals that have been band-limited by the first band limiting unit 301 (S15). Next, the second band limiting unit 304 limits a second band that is not necessary in FM demodulation (the frequency component exceeding the possible maximum frequency of an FM modulated wave), from the two baseband signals outputted from the pulse noise suppressing unit 303 (S16). Lastly, the wave detecting unit 206 obtains an FM demodulated signal from the two baseband signals that have been band-limited by the second band limiting unit 304 (S17). Note that since the details of the respective operations are as described previously, detailed description is omitted here.

As described thus far, in the FM demodulation apparatus 300 in the second embodiment, since pulse noise is precisely suppressed at a preceding stage to the second band limiting unit 304 which has a property that allows pulse noise to expand in the temporal axis direction, it is possible to suppress the expansion of pulse noise in the temporal axis direction. With this, the generation of significant noise in the FM demodulated signal can be suppressed, and it is possible to reduce sound quality deterioration due to pulse noise.

Furthermore, since frequency components other than what is desired are limited by the first band limiting unit 301, there is the advantage of lessening instances in which signals other than pulse noise, such as an FM signal of another frequency, are mistakenly detected as pulse noise by the pulse noise detecting unit 302. In addition, since a configuration which includes the first downsampling unit 3012 at a preceding stage to the pulse noise detecting unit 302 and the pulse noise suppressing unit 303 is adopted, there is the advantage that the sampling frequency in the processing by the pulse noise detecting unit 302 and the pulse noise suppressing unit 303 becomes lower, and the amount of computation is lessened.

Note that although in the second embodiment the sampling frequency is downsampled to 1/64 by the first band limiting unit 301, the downsampling ratio is not limited to such, and other ratios are also possible.

Furthermore, although in the second embodiment the pulse noise is suppressed between the first band limiting unit 301 and the second band limiting unit 304, the present invention is not limited to such configuration. In other words, here, pulse noise is suppressed between the first band limiting unit 301 and the second limiting unit 304 since it is assumed that the pulse noise will expand in the temporal axis direction with the second band limiting unit 304 having a narrow cut-off frequency. However, pulse noise may be suppressed at a preceding stage to the first band limiting unit 301.

Furthermore, although in the second embodiment a configuration which includes two band limiting units is exemplified, the number of band limiting units may be three or more. In such chase, it is sufficient to suppress pulse noise at a preceding stage to the band limiting unit having the property which most allows pulse noise to expand in the temporal axis direction. Since the band limiting unit having the property which most allows pulse noise to expand in the temporal axis direction, among the plural band limiting units, is normally the band limiting unit in the last stage, it is sufficient to suppress pulse noise at a preceding stage to the band limiting unit in the last stage.

### Third Embodiment

In the first embodiment, a configuration which includes the pulse noise detecting unit 203 and the pulse noise suppressing unit 204 in between the quadrature conversion unit 202 and the band limiting unit 205. However, it is sufficient to suppress pulse noise at least at a preceding stage to the band limiting unit (the band limiting unit at the last stage in a configuration including plural band limiting units). In the third embodiment, a configuration which includes the pulse noise detecting unit 203 and the pulse noise suppressing unit 204 in between the analog-to-digital conversion unit 201 and the quadrature conversion unit 202 shall be described.

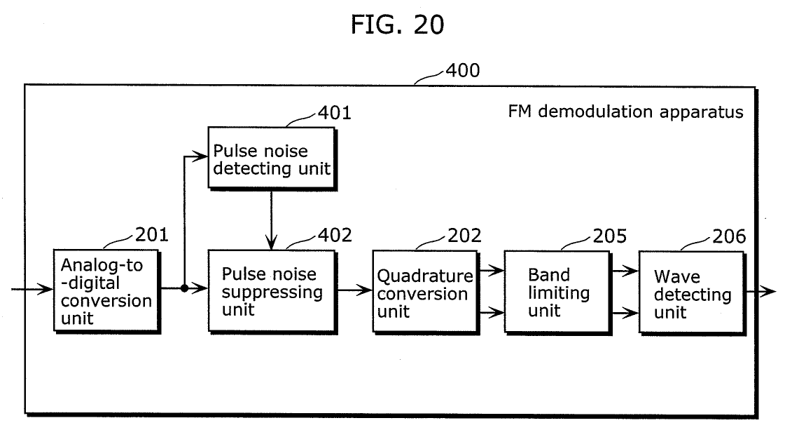

FIG. 20 is a diagram showing the configuration of an FM demodulation apparatus 400 in the third embodiment. As in the first embodiment, the FM demodulation apparatus 400 is a car FM radio, and the like, which performs FM demodulation of an FM modulated wave by digital signal processing, and which functionally includes the analog-to-digital conversion unit 201, the quadrature conversion unit 202, a pulse noise detecting unit 401, a pulse noise suppressing unit 402, the band limiting unit 205, and the wave detecting unit 206. The functions of the analog-to-digital conversion unit 201, the quadrature conversion unit 202, the band limiting unit 205, and the wave detecting unit 206 are the same as those in the first embodiment.

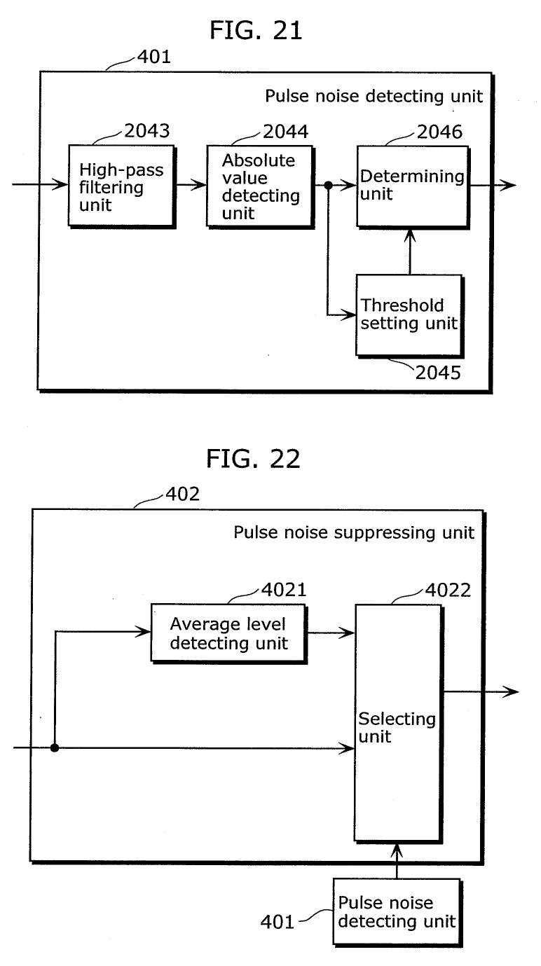

FIG. 21 is a diagram showing the configuration of the pulse noise detecting unit 401. The pulse noise detecting unit 401 includes a high-pass filtering unit 2043, an absolute value detecting unit 2044, a threshold value setting unit 2045, and a determining unit 2046. The functions of these units are the same as those of the respective units in the first embodiment. Since the pulse noise detecting unit 401 in the third embodiment is located between the analog-to-digital conversion unit 201 and the quadrature conversion unit 202, it has one input signal. As such, a constituent unit corresponding to the amplitude detecting unit 2031 in the first embodiment becomes unnecessary.

FIG. 22 is a diagram showing the configuration of the pulse noise suppressing unit 402. The pulse noise suppressing unit 402 includes an average level detecting unit 4021 and a selecting unit 4022. Since the pulse noise suppressing unit 402 also has one input signal, the number of average level detecting units also becomes one, and the input and output of the selecting unit 4022 also becomes one. Other points are the same as with the pulse noise suppressing unit 204 in the first embodiment.

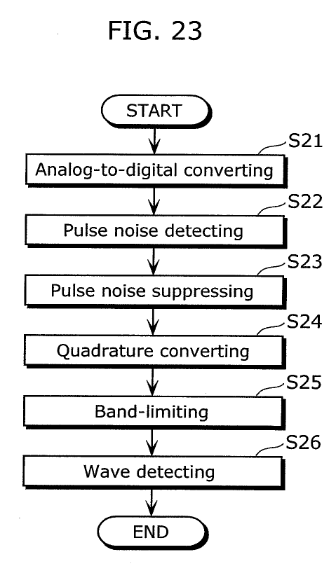

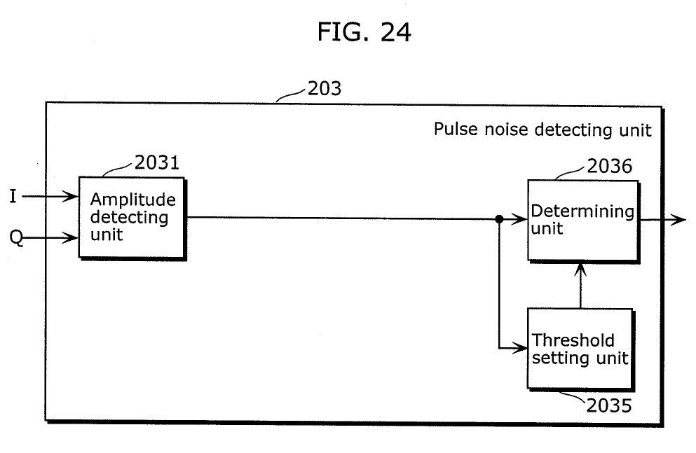

FIG. 23 is a flowchart showing the operation of the FM demodulation apparatus 400 in the third embodiment. First, the analog-to-digital conversion unit 201 converts an FM modulated analog signal into a digital signal (S21). Next, the pulse noise detecting unit 401 detects the pulse noise included in the digital signal outputted from the analog-to-digital conversion unit 201 (S22). Next, the pulse noise suppressing unit 402 suppresses the pulse noise detected by the pulse noise detecting unit 401, in the digital signal outputted from the analog-to-digital conversion unit 201 (S23). Next, the quadrature conversion unit 202 quadrature-converts the digital signal outputted from the pulse suppressing unit 402 into two mutually quadratic baseband signals (S24). Next, the band limiting unit 205 limits bands that are not necessary in FM demodulation from the two baseband signals outputted from the quadrature conversion unit 202 (S25). Lastly, the wave detecting unit 206 obtains an FM demodulated signal from the two baseband signals that have been band-limited by the band limiting unit 205. Note that since the details of the respective operations are as described previously, detailed description is omitted here.

As described thus far, since the FM demodulation apparatus 400 in the third embodiment adopts a configuration which includes the pulse noise detecting unit 401 and the pulse noise suppressing unit 402 between the analog-to-digital conversion unit 201 and the quadrature conversion unit 202, the FM demodulation apparatus 400 can precisely suppress pulse noise before band-limiting. In other words, as a result of being able to avoid the problem of pulse noise expanding in the temporal axis direction and being able to suppress the generation of significant noise in the FM demodulated signal, it becomes possible to reduce sound quality deterioration due to pulse noise.

Furthermore, with the FM demodulation apparatus 400 in the third embodiment, there is an advantage in that the configuration of the pulse noise detecting unit 401 and the pulse noise suppressing unit 403 is simplified.

Note that although description is carried out in the first through third embodiments by exemplifying an FM demodulation apparatus, the modulation method is not limited to FM. In other words, the present invention can be applied to demodulation apparatuses which adopt other modulation methods as long as it is an apparatus having the problem of pulse noise expanding in the temporal axis direction due to band-limiting.

Furthermore, although a configuration in which the pulse noise detecting unit 203 includes the high-pass filtering unit 2033 and the absolute value detecting unit 2034 is exemplified in FIG. 9, the present invention is not limited to such configuration. In other words, as shown in FIG. 24, a configuration in which the pulse noise detecting unit 203 does not include the high-pass filtering unit 2033 and the absolute value detecting unit 2034 may also be adopted. In this case, the pulse noise detecting unit 203 detects, as the pulse noise term, the term in which the amplitude values of the two baseband signals outputted from the quadrature conversion unit 202 exceed the threshold.

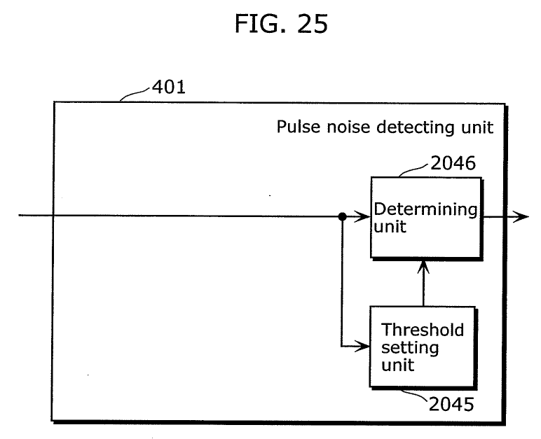

In the same manner, although a configuration in which the pulse noise detecting unit 401 includes the high-pass filtering unit 2043 and the absolute value detecting unit 2044 is exemplified in FIG. 21, the present invention is not limited to such configuration. In other words, as shown in FIG. 25, a configuration in which the pulse noise detecting unit 401 does not include the high-pass filtering unit 2043 and the absolute value detecting unit 2044 may also be adopted. In this case, the pulse noise detecting unit 401 detects, as the pulse noise term, the term in which the amplitude value of the signal outputted from the analog-to-digital conversion unit 201 exceeds the threshold.

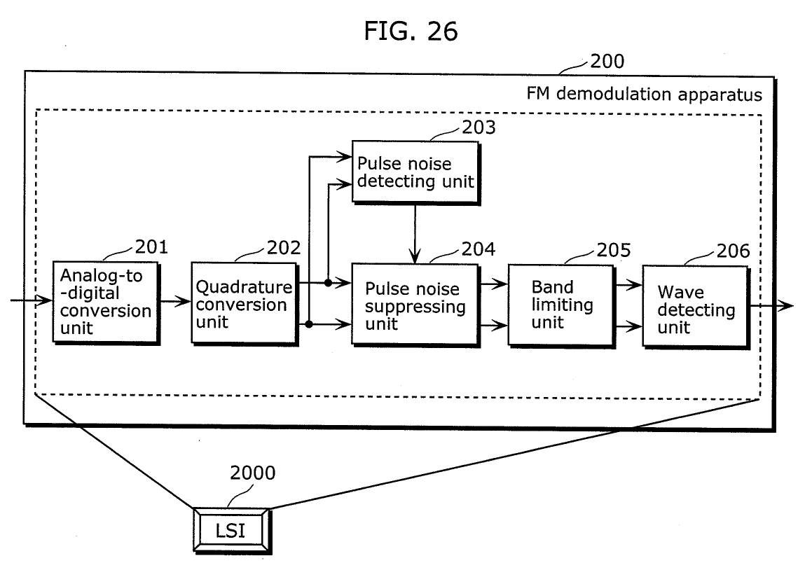

FIG. 26 is a diagram showing an example of the case where the constituent units of the FM demodulation apparatus 200 in the first embodiment are made as an integrated circuit. The FM demodulation apparatus 300 in the second embodiment and the FM demodulation apparatus 400 in the third embodiment can likewise be made as integrated circuits.

An LSI 2000, which is an example of an integrated circuit, implements the functions of the constituent units included in the area enclosed by the dotted line. The integrated circuit can also be called an IC, a system LSI, a super LSI, and an ultra LSI, depending on the degree of integration. The integrated circuit is not limited to an LSI, and may also be implemented through a dedicated circuit or a general-purpose processor. A Field Programmable Array (FPGA) which allows a program to be stored after LSI manufacturing, or a reconfigurable processor which allows reconfiguration of the connections and settings of circuit cells within the LSI may also be used. Should circuit integration technology replacing the LSI (biotechnology, organic chemistry technology) emerge as a result of progress in semiconductor technology or other derivative technology, it is obvious that such technology may be used in the integration of the above-mentioned functions.

### INDUSTRIAL APPLICABILITY

The audio signal demodulation apparatus according to the present invention has the effect of suppressing pulse noise and is useful as a car FM radio, and the like, which uses a transmission system in which pulse noise mixes-in.

1. An audio signal demodulation apparatus which demodulates a modulated wave obtained by modulating an audio signal, said audio signal demodulation apparatus comprising:
an analog-to-digital conversion unit operable to convert a modulated analog signal into a digital signal;
a quadrature conversion unit operable to convert, into two mutually quadratic baseband signals, the digital signal converted by said analog-to-digital conversion unit;
a band limiting unit operable to limit a frequency component in the two baseband signals converted by said quadrature conversion unit, the frequency component exceeding a possible maximum frequency of the modulated wave;
a detecting unit operable to obtain a demodulated signal from the two baseband signals that have been band-limited by said band limiting unit; and
a pulse noise suppressing unit operable to suppress pulse noise included in the signals inputted to said band limiting unit.

2. The audio signal demodulation apparatus according to claim 1, wherein said pulse noise suppressing unit is provided between said quadrature conversion unit and said band limiting unit.

3. The audio signal demodulation apparatus according to claim 1, further comprising:
a preprocessing band limiting unit operable to limit a frequency component exceeding the maximum frequency, as preprocessing for the suppression of the pulse noise,
wherein said pulse noise suppressing unit is provided between said preprocessing band limiting unit and said band limiting unit.

4. The audio signal demodulation apparatus according to claim 1, wherein said pulse noise suppressing unit is provided between said analog-to-digital conversion unit and said quadrature conversion unit.

5. The audio signal demodulation apparatus according to claim 1, wherein said pulse noise suppressing unit is operable to detect, as a pulse noise term, a term in which amplitude values of the inputted signals exceed a threshold.

6. The audio signal demodulation apparatus according to claim 5, wherein said pulse noise suppressing unit is operable to set, as the amplitude values, a sum of squares or a square root of a sum of squares of the inputted signals.

7. The audio signal demodulation apparatus according to claim 5, wherein said pulse noise suppressing unit is operable to set, as the amplitude values, a sum or an average of absolute values of the inputted signals.

8. The audio signal demodulation apparatus according to claim 5, wherein said pulse noise suppressing unit is operable to set, as the threshold, a predetermined multiple of an average of absolute values of the inputted signals.

9. The audio signal demodulation apparatus according to claim 1, wherein said pulse noise suppressing unit is operable to output an average of amplitude values of the inputted signals for a term in which the pulse noise is detected, and to output the inputted signals for a term in which the pulse noise is not detected.

10. A car radio comprising:
an analog-to-digital conversion unit operable to convert a modulated analog signal into a digital signal;
a quadrature conversion unit operable to convert, into two mutually quadratic baseband signals, the digital signal converted by said analog-to-digital conversion unit;
a band limiting unit operable to limit a frequency component in the two baseband signals converted by said quadrature conversion unit, the frequency component exceeding a possible maximum frequency of the modulated wave;
a detecting unit operable to obtain a demodulated signal from the two baseband signals that have been band-limited by said band limiting unit; and
a pulse noise suppressing unit operable to suppress pulse noise included in the signals inputted to said band limiting unit.

11. An audio signal demodulation method for demodulating a modulated wave obtained by modulating an audio signal, said method comprising:
an analog-to-digital conversion step of converting a modulated analog signal into a digital signal;
a quadrature conversion step of converting, into two mutually quadratic baseband signals, the digital signal converted in said analog-to-digital conversion step;
a band limiting step of limiting a frequency component in the two baseband signals converted in said quadrature conversion step, the frequency component exceeding a possible maximum frequency of the modulated wave;
a detecting step of obtaining a demodulated signal from the two baseband signals that have been band-limited in said band limiting step; and
a pulse noise suppressing step of suppressing pulse noise included in the signals to be band-limited in said band limiting step.

12. A program for demodulating a modulated wave into which an audio signal has been modulated, said program causing a computer to execute:
an analog-to-digital conversion step of converting a modulated analog signal into a digital signal;
a quadrature conversion step of converting, into two mutually quadratic baseband signals, the digital signal converted in said analog-to-digital conversion step;
a band limiting step of limiting a frequency component in the two baseband signals converted in said quadrature conversion step, the frequency component exceeding a possible maximum frequency of the modulated wave;
a detecting step of obtaining a demodulated signal from the two baseband signals that have been band-limited in said band limiting step; and
a pulse noise suppressing step of suppressing pulse noise included in the signals to be band-limited in said band limiting step.

13. An integrated circuit which demodulates a modulated wave into which an audio signal has been modulated, said audio signal demodulation apparatus comprising:
an analog-to-digital conversion unit operable to convert a modulated analog signal into a digital signal;
a quadrature conversion unit operable to convert, into two mutually quadratic baseband signals, the digital signal converted by said analog-to-digital conversion unit;
a band limiting unit operable to limit a frequency component in the two baseband signals converted by said quadrature conversion unit, the frequency component exceeding a possible maximum frequency of the modulated wave;
a detecting unit operable to obtain a demodulated signal from the two baseband signals that have been band-limited by said band limiting unit; and
a pulse noise suppressing unit operable to suppress pulse noise included in the signals inputted to said band limiting unit.
